(19) United States
(12) Patent Application Publication
(10) Pub. No.: US 2026/0156932 A1
(43) Pub. Date: Jun. 4, 2026

(54) SELF-ALIGNED BACKSIDE CONTACT FORMATION FOR STACKED FET

(71) Applicant: INTERNATIONAL BUSINESS MACHINES CORPORATION, ARMONK, NY (US)

(72) Inventors: Shahrukh Khan, Sandy Hook, CT (US); Ruilong Xie, Niskayuna, NY (US); Kisik Choi, Watervliet, NY (US); Shay Reboh, Guilderland, NY (US); Junli Wang, Slingerlands, NY (US); Tenko Yamashita, Schenectady, NY (US)

(21) Appl. No.: 18/967,976

(22) Filed: Dec. 4, 2024

(51) Int. Cl. H10D 84/85; H10D 30/01; H10D 30/43; H10D 30/67; H10D 62/10; H10D 64/23

(52) U.S. Cl. CPC H10D 84/853; H10D 30/014; H10D 30/43; H10D 30/6757; H10D 64/254; H10D 30/6735; H10D 62/121

(57) ABSTRACT

A microelectronic structure that includes a stacked FET that includes an upper FET and a lower FET, wherein the upper FET includes a NFET source/drain and the lower FET includes a PFET source/drain, wherein the PFET source/drain extends past a backside surface of a lower gate of the lower FET into a backside region of the stacked FET. A first backside interlayer dielectric layer located adjacent to a sidewall of the PFET source/drain that extends into the backside region. A second backside interlayer dielectric layer located on a backside surface of the first backside interlayer dielectric layer. A backside contact located on a backside surface of the PFET source/drain.

### BACKGROUND

The present invention generally relates to the field of microelectronics, and more particularly to forming backside contacts in a stack FET.

Establishing the connection between the two or more metal layers within a microelectronic structure often includes various processes, such as, but not limited to removal/etching and/or patterning/lithography. During these processes, the alignments of the via connections may vary as a result of any number of inconsistencies during these processes. A self-aligned contact (SAC) is a technique that ensures the source and drain of the microelectronic structure are aligned by adding a protective dielectric layer over the transistor gate in order to prevent contact-to-gate shorts.

### BRIEF SUMMARY

Additional aspects and/or advantages will be set forth in part in the description which follows and, in part, will be apparent from the description, or may be learned by practice of the invention.

A microelectronic structure that includes a stacked FET that includes an upper FET and a lower FET, wherein the upper FET includes a NFET source/drain and the lower FET includes a PFET source/drain, wherein the PFET source/drain extends past a backside surface of a lower gate of the lower FET into a backside region of the stacked FET. A first backside interlayer dielectric layer located adjacent to a sidewall of the PFET source/drain that extends into the backside region. A second backside interlayer dielectric layer located on a backside surface of the first backside interlayer dielectric layer. A backside contact located on a backside surface of the PFET source/drain, wherein the backside contact includes a head portion and a protrusion portion, wherein the protrusion portion of the backside contact is horizontally adjacent to the first backside interlayer dielectric layer, and wherein the protrusion portion of the backside contact extends into the PFET source/drain.

A microelectronic structure that includes a first stacked FET, wherein the first stacked FET includes a first upper FET and a first lower FET, wherein the first lower FET includes a includes a first PFET source/drain, wherein the first PFET source/drain extends past a backside surface of a lower gate into a backside region of the first stacked FET to a first depth. A second stacked FET, wherein the second stacked FET includes a second upper FET and a second lower FET, wherein the second lower FET includes a second PFET source/drain, wherein the second PFET source/drain extends past the backside surface of the lower gate into a backside region of the second stacked FET to a second depth, wherein the first depth and the second depth are different. A first backside interlayer dielectric layer located adjacent to a sidewall of the first PFET source/drain and a sidewall of the second PFET source/drain, wherein the first backside interlayer dielectric layer extends into the backside region of the first stacked FET and the backside region of the second stacked FET. A second backside interlayer dielectric layer located on a backside surface of the first backside interlayer dielectric layer and a backside surface of the second PFET source/drain.

A method comprising forming a stacked FET that includes an upper FET and a lower FET, wherein the upper FET includes a NFET source/drain, and the lower FET includes a PFET source/drain, wherein the PFET source/drain extends past a backside surface of a lower gate of the lower FET into a backside region of the stacked FET. Forming a first backside interlayer dielectric layer located adjacent to a sidewall of the PFET source/drain that extends into the backside region. Forming a second backside interlayer dielectric layer located on a backside surface of the first backside interlayer dielectric layer. Forming a backside contact located on a backside surface of the lower source/drain, wherein the backside contact includes a head portion and a protrusion portion, wherein the protrusion portion of the backside contact is horizontally adjacent to the first backside interlayer dielectric layer, and wherein the protrusion portion of the backside contact extends into the PFET source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of the microelectronic structure, in accordance with the embodiment of the present invention.

FIG. 2 illustrates a cross-section X of the microelectronic structure, in accordance with the embodiment of the present invention.

FIG. 3 illustrates the cross-section X of the microelectronic structure after frontside processing, in accordance with the embodiment of the present invention.

FIG. 4 illustrates the cross-section X of the microelectronic structure after flipping of the device over for backside processing and after first substrate removal, in accordance with the embodiment of the present invention.

FIG. 5 illustrates the cross-section X of the microelectronic structure after the removal of the etch stop layer and after second substrate removal, in accordance with the embodiment of the present invention.

FIG. 6 illustrates the cross-section X of the microelectronic structure after the formation of a first backside interlayer dielectric layer, in accordance with the embodiment of the present invention.

FIG. 7 illustrates the cross-section X of the microelectronic structure after the formation of a second backside interlayer dielectric layer, in accordance with the embodiment of the present invention.

FIG. 8 illustrates the cross-section X of the microelectronic structure after patterning of the second backside interlayer dielectric layer, in accordance with the embodiment of the present invention.

FIG. 9 illustrates the cross-section X of the microelectronic structure after gouging of the first lower PFET source/drain, in accordance with the embodiment of the present invention.

FIG. 10 illustrates the cross-section X of the microelectronic structure after the formation of the backside contact with a backside cavity of the gouged first lower PFET source/drain, in accordance with the embodiment of the present invention.

FIG. 11 illustrates the cross-section X of the microelectronic structure after the formation of the backside interconnect, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards a stacked FET in which there is a self-aligned backside contact without the need for a self-aligned contact (SAC) due to the selective etching of two backside interlayer dielectric layers. In each stack FET of the present invention the lower FET includes a PFET source/drain extending past a backside surface of a lower gate into a backside region of the stacked FET. The first PFET source/drain acting as a placeholder which is gouged to increase the contact surface area.

A stack FET cell includes one upper transistor and one lower transistor with opposite polarity (e.g., one is an NFET, and the other is PFET). Stack FET scaling may be challenging because the need for wiring multiple components may impose space restrictions. Additionally, backside contact formation with scaled CPP (Contacted Poly Pitch) is difficult on multiple fronts, included, but not limited to including, placeholder formation and non-self-aligned contact (SAC) formation. Forming a placeholder which is self-aligned to the source and drain region for the stack FET is very difficult and may become even more difficult when we do not have a SAC process. A SAC process may be more forgiving to misalignment in the source and drain contact formation to the adjacent gates. The present invention includes a SAC cap on the upper gates of the frontside/upper FET but does not require a SAC cap on the lower gates of the backside/lower FET due to the use of multiple selectively etchable dielectric layers, which will be explained in greater detail below.

The present invention is directed to a stacked FET in which the lower/bottom transistor is the PFET, and the upper/top transistor is the NFET, wherein the PFET source/drain extends deeper than the gate and the inner spacers into the second substrate/backside region. By extending the lower PFET source/drain into the second substrate deeper than the backside surface of the gate and inner spacers the PFET source/drain may act as a placeholder which may be gouged in forming the backside contact. The invention enables stacked FET with a self-aligned backside contact without the need for an SAC on the backside by using two selectively etchable interlayer dielectric layers. The first backside interlayer dielectric layer and the second backside interlayer dielectric layer, being different materials such that may be selectively etched. The backside contact having a head portion and protrusion portion. The protrusion portion is within/horizontally adjacent to the first backside interlayer dielectric layer and gauged into the first lower PFET source/drain (e.g., first lower PFET SiGe source/drain epi). The protrusion portion of the backside contact gauging into the first lower PFET source/drain and traversing the width of the first lower PFET source/drain increasing the contact area. The protrusion portion having a critical dimension/width less than the critical dimension/width of the head portion of the backside contact. The head portion of the backside contact being within/horizontally adjacent to the second backside interlayer dielectric layer. This ensures that the metallized portion is contacting the width of the source/drain reducing contact resistance. Additionally, this ensures, by design you have a backside contact that is traversing the width of the source/drain. This may be critical because the larger overlap of the contact with the source/drain cavity, specifically when the CPPs are scaled, is critical for the contact resistance aspects of the FET performance.

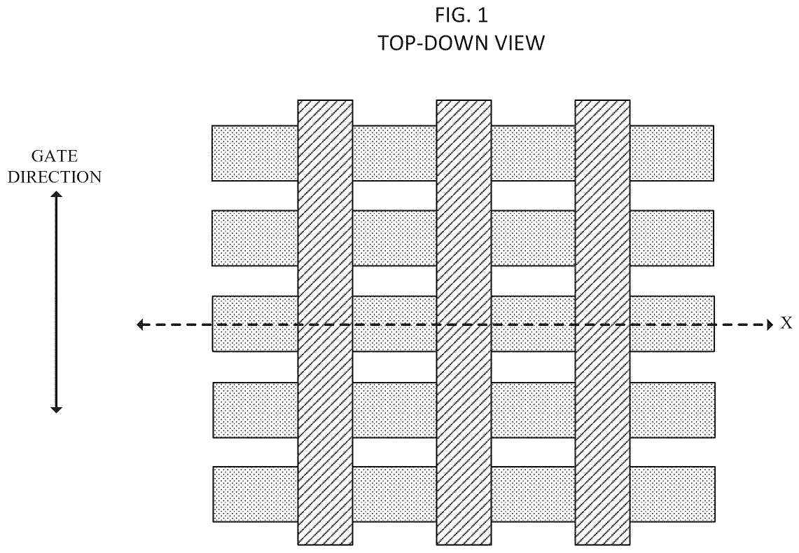

FIG. 1 illustrates a top-down view of multiple devices, in accordance with the embodiment of the present invention including the gate direction (across the gate). The cross-section X extends horizontally through nanosheet transistors and perpendicular to the gate direction (cross-section X is perpendicular across the gate).

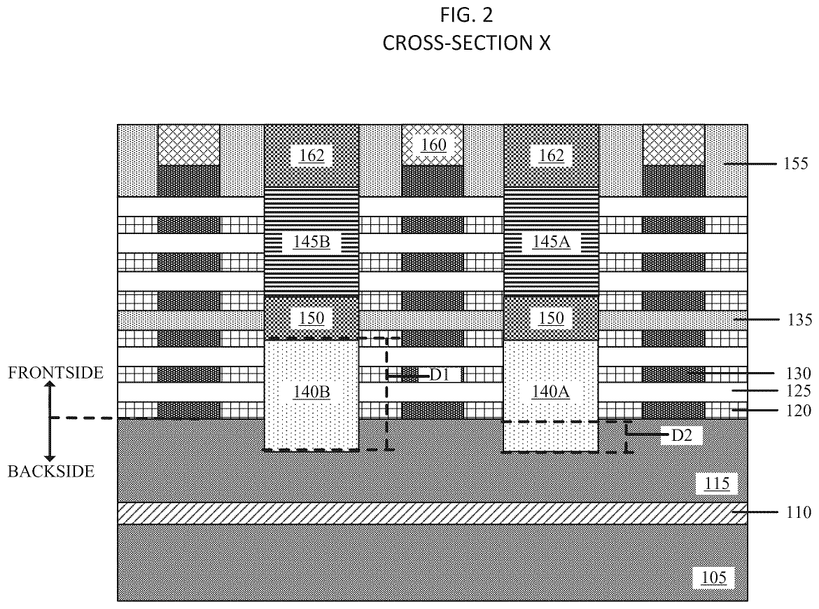

FIG. 2 illustrates the microelectronic structure during an intermediate step of the frontside fabrication process, that includes a first substrate 105, an etch stop 110, a second substrate 115, inner spacer 120, channel layers 125, gate 130, middle dielectric isolation layer 135, a first lower PFET source/drain 140A (e.g., first PFET source/drain 140A), a second lower PFET source/drain 140B (e.g., second PFET source/drain), a first upper NFET source/drain 145A (e.g., first NFET source/drain 145A), a second upper NFET source/drain 145B (e.g., second NFET source/drain 145B). The first PFET source/drain 140A and the second PFET source/drain 140B extending towards the backside of the microelectronic structure past the backside surface of the gate 130 surface and the backside surface of the inner spacer 120 to a depth D2 within the second substrate 115. The first PFET source/drain 140A and the second PFET source/drain 140B having a total depth D1 and a depth D2 extending past the backside surface of the gate 130. The portions illustrated by depth D2 can act as a placeholder for the formation of backside contacts which will be described in further detail below. The depth/dimension of D2 illustrated by FIG. 2 is for exemplar purposed only, such that the depth D2 can be greater or less than what is illustrated as long as the PFET source/drains 140A/140B extends past the backside surface of the gate 130 for a distance. The total depth D1 of the PFET source/drains may also vary based on the depth D2 and/or vary between the first PFET source/drain 140A and the second PFET source/drain 140 due to variations in the manufacturer process.

The lower frontside interlayer dielectric layer 150 may be formed in between the first lower PFET source/drain 140A and the first upper NFET source/drain 145A, as well as, between the second lower PFET source/drain 140B and the second upper NFET source/drain 145B. The microelectronic structure further includes a frontside interlayer dielectric layer 155, self-aligned contact (SAC) cap 160, and upper frontside interlayer dielectric layer 162. The lower frontside interlayer dielectric layer 150, the frontside interlayer dielectric layer 155, and the upper interlayer dielectric layer can be the same or different materials. The SAC cap 160 may be formed on the frontside of the gate 130 and act as an etch stop layer to prevent shorting on the frontside of the microelectronic structure.

The first substrate 105 and the second substrate 115 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the first substrate 105 and the second substrate 115. In some embodiments, the first substrate 105 and the second substrate 115 includes both semiconductor materials and dielectric materials. The first substrate 105 and the second substrate 115 of the microelectronic structure may also comprise an organic semiconductor or a layered semiconductor such as, for example, Si/SiGe, a silicon-on-insulator or a SiGe-on-insulator. A portion or the entire the first substrate 105 and the second substrate 115 of the microelectronic structure may also be comprised of an amorphous, polycrystalline, or monocrystalline. The first substrate 105 and the second substrate 115 of the microelectronic structure may be doped, undoped or contain doped regions and undoped regions therein.

The source/drains 140A, 140B, 145A, 145B, including, but not limited to including, a first lower PFET source/drain 140A, a second lower PFET source/drain 140B, a first upper NFET source/drain 145A, and a second upper NFET source/drain 145B. In this invention, the backside source/drains (e.g., 140A/140B) may be p-type epitaxy and the frontside source/drains (e.g., 145A/145B) may be a n-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

Gate 130 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

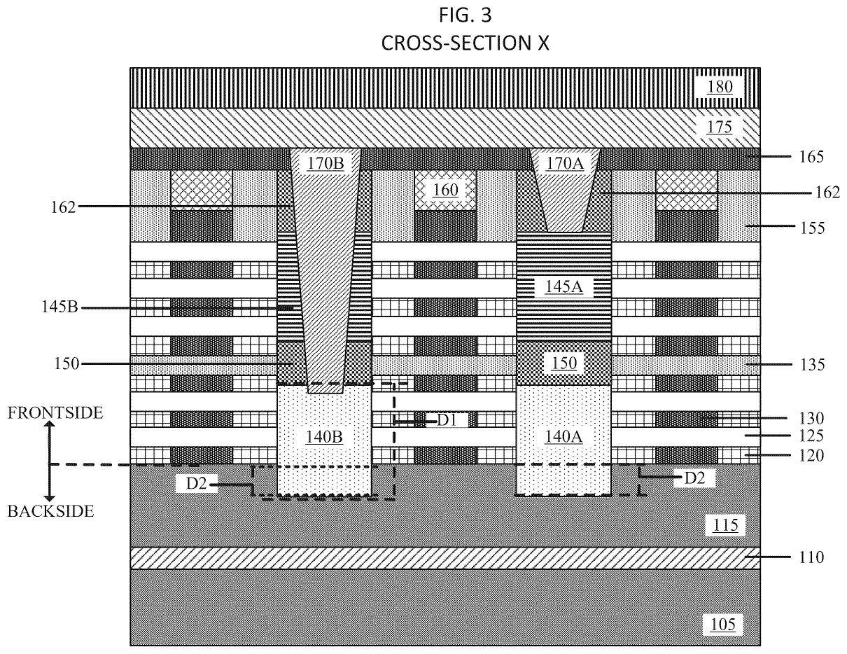

FIG. 3 illustrates the processing stage after frontside processing, including the formation of the middle-of-line (MOL) layer 165, a first frontside contact 170A, a second frontside contact 170B, the back-end-of-line (BEOL) layer 175 (e.g., frontside interconnect 175), and the carrier wafer 180. After the formation of the MOL layer 165 a lithography layer (not shown) is formed on the frontside surface of the MOL layer 165. A plurality of trenches (not shown) are formed by patterning the lithography layer, the MOL layer 165, the upper frontside interlayer dielectric layer 162, the second upper NFET source/drain, the lower frontside interlayer dielectric layer 150, and the second lower PFET source/drain. The first frontside contact 170A and the second frontside contact 170B are formed by filling the plurality of trenches (not shown) with a conductive metal as part of a metallization process. The first frontside contact 170A extending from the frontside surface of the MOL layer 165 through the upper frontside interlayer dielectric layer 162 to the frontside surface of the first upper NFET source/drain. The second frontside contact 170B extending from the frontside surface of the MOL layer 165 through the upper frontside interlayer dielectric layer 162, through the second upper NFET source/drain, through the lower frontside interlayer dielectric layer 150, and past the frontside surface of the second lower PFET source/drain. The second frontside contact 170B acts as a CMOS Inverter structure that ties together the second lower PFET source/drain 140B (e.g., second PFET source/drain) and the second upper NFET source/drain 145B (e.g., second NFET source/drain 145B). The lithography layer (not shown) is removed and the BEOL layer 175 (e.g., frontside interconnect 175) is formed on the frontside surface of the MOL layer 165, frontside surface of the first frontside contact 170A, and frontside surface of the second frontside contact 170B. Frontside interconnect 175 (e.g., BEOL layer 175) can be comprised of one more layers/levels, one or more via(s), and one or more metal lines. Frontside interconnect 175 (e.g., BEOL layer 175) is illustrated as one layer for simplicity reasons only. The carrier wafer 180 is formed on top of the frontside surface of the BEOL layer 175 (e.g., Frontside interconnect 175). The carrier wafer 180 allows for the microelectronic structure to be flipped over for backside processing.

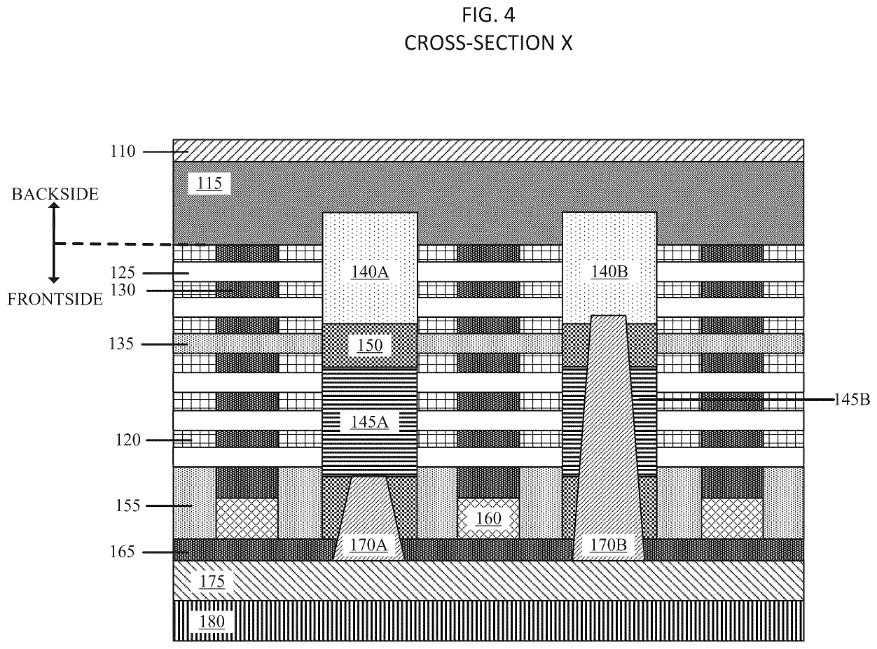

FIGS. 4-11 illustrate the processing stage after flipping the microelectronic structure over for backside processing. Carrier wafer 180 allows for the microelectronic structure (logic device, or logic device with a passive device) to be flipped over for backside processing, i.e., flipping over the nanosheet transistor exposes the backside region of the device. FIGS. 2-3 illustrated the frontside processing of the microelectronic structure and FIGS. 4-11 illustrate the backside processing of the microelectronic structure.

FIG. 4 illustrates processing stage after flipping of the device over for backside processing and after first substrate 105 removal. The first substate 105 may be removed utilizing one or more removal/etching processes exposing the backside surface of the etch stop layer 110.

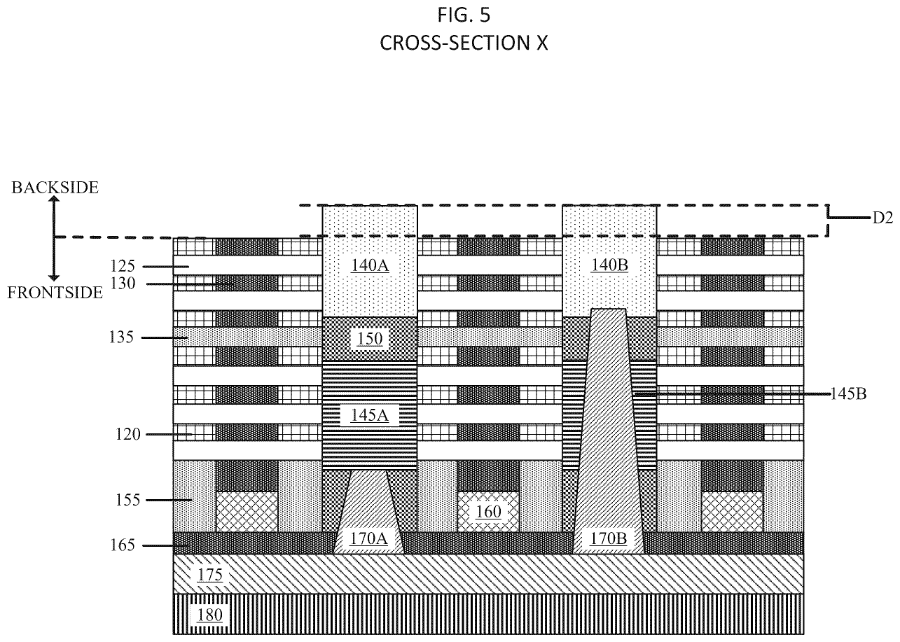

FIG. 5 illustrates the processing stage after the removal of the etch stop layer 110 and after second substrate 115 removal. The etch stop layer 110 and the second substrate 115 may be removed utilizing one or more removal/etching processes. The removal of the etch stop layer 110 and the second substrate 115 exposing a backside surface of the inner spacers 120 and gate 130 as well as a portion of the first PFET source/drain 140A and the second PFET source/drain 140B extending past a backside surface of the gate 130 to the depth/height/dimension D2.

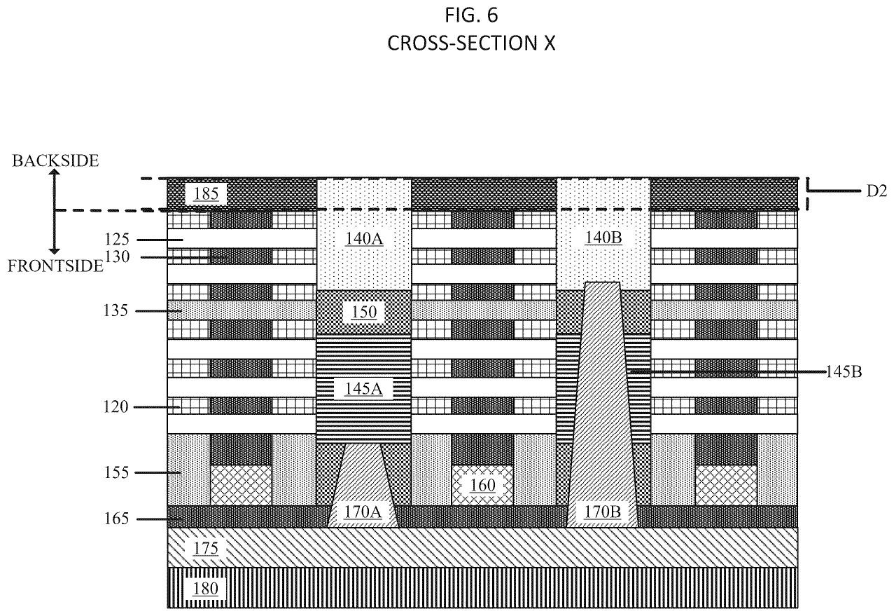

FIG. 6 illustrates the processing stage after the formation of a first backside interlayer dielectric layer 185. The first backside interlayer dielectric layer 185 may be formed on the backside of the inner spacers 120 and gate 130, covering the previously exposed side portions of the first lower PFET source/drain 140A and the second lower PFET source/drain 140B. The backside of the first backside interlayer dielectric layer 185 being level with the backside of the first lower PFET source/drain 140A and the backside of the second PFET source/drain 140B following chemical mechanical planarization (CMP). The end result being the backside surface of the first PFET source/drain 140A and the backside surface of the second PFET source/drain 140B is exposed, with the depth D2 of the first backside interlayer dielectric layer 185 being substantially equal/similar to the depth/dimension of the source/drains 140A/140B extending past the backside surface of the gate 130, as emphasized by depth/dimension/height D2. Depth/dimension/height D2 as illustrated in FIG. 6 might slightly differ than the depth D2 illustrated in FIGS. 2-5, due to variations from the manufacturer process, for example, the planarization process.

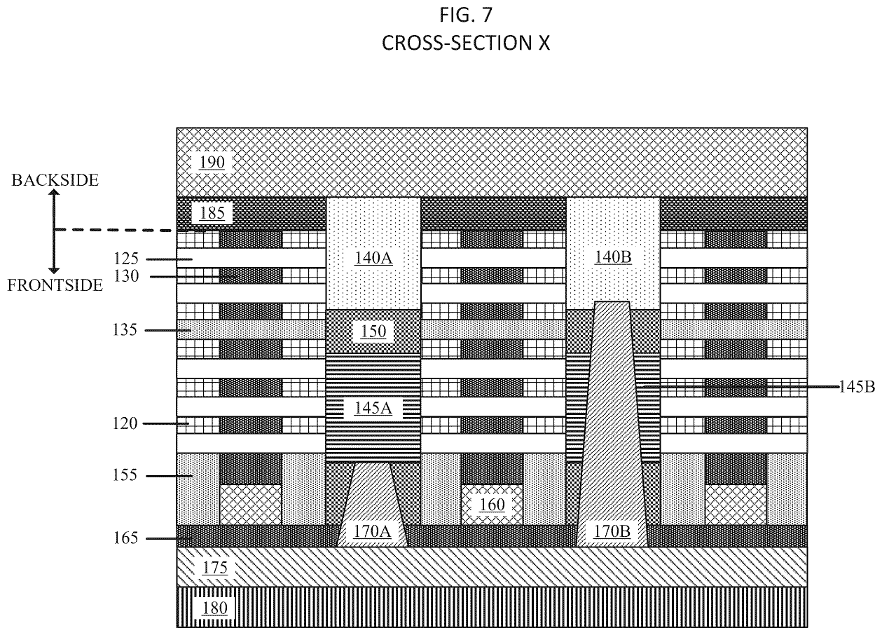

FIG. 7 illustrates the processing stage after the formation of a second backside interlayer dielectric layer 190. The second backside interlayer dielectric layer 190 being formed on the backside surface of the first backside interlayer dielectric layer 185, the backside surface of the first PFET source/drain 140A, and the backside surface of the second PFET source/drain 140B. The first backside interlayer dielectric layer 185 is comprised of a first material and the second backside interlayer dielectric layer 190 is comprised of a second material. The first material and the second material are different materials. As described in further detail below, the first material comprising the first interlayer dielectric layer 185 and the second material comprising the second backside interlayer dielectric layer 190 are different materials such that they can be selectively etched.

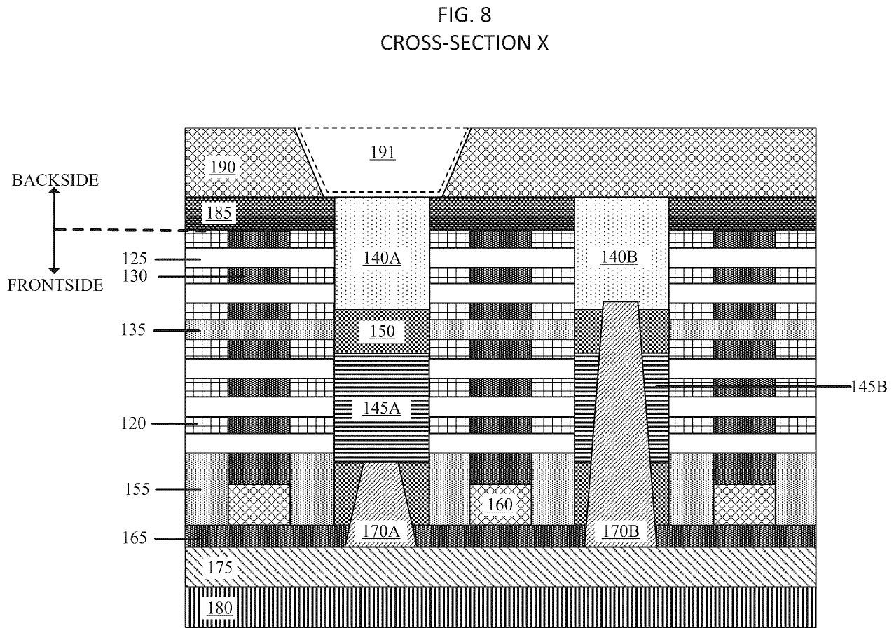

FIG. 8 illustrates the processing stage after patterning of the second backside interlayer dielectric layer 190. A lithography layer (not shown) is formed on the backside of the second backside interlayer dielectric layer 190. A portion of the lithography layer (not shown) is patterned to expose a portion of the second backside interlayer dielectric layer 190 above the backside surface of the first PFET source/drain 140A. The backside interlayer dielectric layer 190 is etched to form a head portion of the backside contact trench 191, emphasized by dashed shape 191. The lithography layer is removed.

The head portion backside contact trench 191 may extend down to the backside surface of the first PFET source/drain 140A. The alignment, size, shape, and location of the head portion backside contact trench 191 may depend on variations in the fabrication process. While FIG. 8 illustrates an ideal alignment scenario for the head portion of the backside contact trench 191, this is not meant to be seen as limiting to the present invention. In the ideal alignment scenario illustrated by FIG. 8 the head portion of the backside contact trench 191 extends horizontally exposing the entire backside surface of the first PFET source/drain 140A and a portion of the backside surface of the first backside interlayer dielectric layer 185 on both sides of the first lower PFET source/drain 140A. However, in other alignment scenarios (not shown), only a portion of the backside surface of the first lower PFET source/drain 140A may be exposed by the head portion of the backside contact trench 191. The portion of the backside surface of the first interlayer dielectric layer 185 exposed on each side of the first lower PFET source/drain 140A may also be less than or greater than the portion illustrated in FIG. 8. Additionally, in other scenarios (not shown), a portion of the backside of the first backside interlayer dielectric layer 185 on only one side of the first lower PFET source/drain 140A may be exposed. Furthermore, in other scenarios, the backside surface of the first backside interlayer dielectric layer 185 may not be exposed at all.

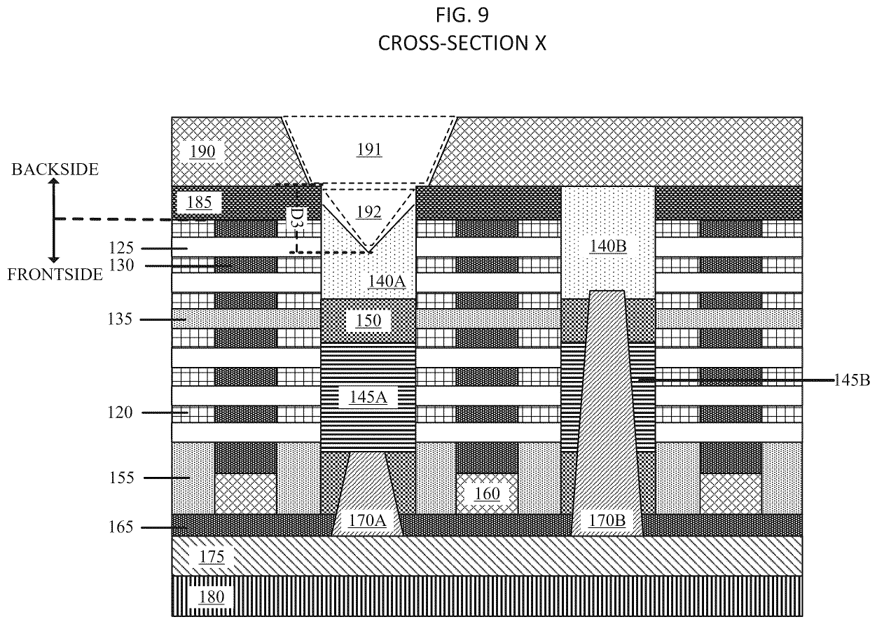

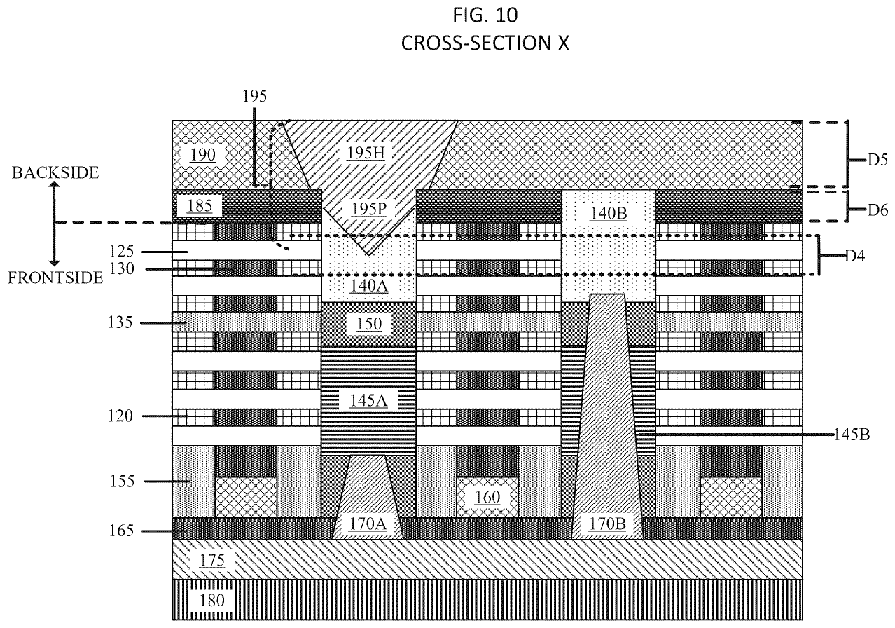

FIG. 9 illustrates the processing stage after gouging of the first lower PFET source/drain 140A. The gouging process is utilized to remove a portion of the of the first PFET source/drain 140A to extend the head portion of the backside contact trench 191 to include a gouged/protrusion portion of the backside contact trench 192. FIG. 9 illustrates a triangular shaped gouge, this is not meant to be seen as limiting to the present invention, the shape of the gouged/protrusion portion of the backside contact trench 192 can be a concave shape, trapezoidal shape, some other shape and/or combination of shapes that is the result from the gouging process. The gouged/protrusion portion of the backside contact trench 192 has a depth/height/dimension D3, wherein a bottom/deepest portion of the gouged/protrusion portion of the backside contact trench 192 can be within the thickness of the first channel layer 125 (e.g., the channel layer 125 that is closest to the backside region). The depth/height/dimension D3 as illustrated by FIG. 9 is not meant to be limiting. For example, the depth/height/dimension D3 of the gauge may range from the backside surface of the first channel layer 125 (i.e., the channel closes to the backside region) to various depths within the first PFET source/drain 140A towards but not reaching the frontside surface of the lower frontside interlayer dielectric layer 150. The range of depths will be described in further detail in FIG. 10 with respect to the depth of the protrusion portion 195P of the backside contact 195.

The protrusion portion of the backside contact trench 192 extends the head portion of the backside contact trench 191 downward towards the frontside of the microelectronic structure. The protrusion portion backside contact trench 192 gouging into the silicon germanium (SiGe) or other material comprising the first PFET source/drain 140A. While the shape/depth/dimension of the protrusion portion backside contact trench 192 may vary, as described in greater detail above, it traverses the width of the first PFET source/drain 140A, this is important because the larger overlap of this contact with the source/drain of the first PFET source/drain 140A, which may be critical for aspects of the FET performance, such as reducing contact resistance.

FIG. 10 illustrates the processing stage after the formation of the backside contact 195. The backside contact 195 includes a head portion 195H and a protrusion portion 195P. A metallization process is utilized to fill the head portion of the backside contact trench 191 and the gouged/protrusion portion of the backside contact trench 192 with conductive material to form the backside contact 195. The head portion of the backside contact 195 being within/horizontally adjacent to the second backside interlayer dielectric layer 190. The head portion or the backside most portion of the backside contact 195H having a depth/dimension D5 equivalent to the depth/dimension of the second backside interlayer dielectric layer 190. As described in greater detail at FIG. 8, the alignment, size, shape, and location of the head portion of the backside contact 195H may vary as a result of any number of inconsistencies during the fabrication processes across the processing stages. While FIG. 10 illustrates the head portion of the backside contact 195H in an ideal alignment scenario, this is not meant to be seen as limiting to the present invention.

The protrusion portion of the backside contact 195P is within/horizontally adjacent to the first backside interlayer dielectric layer 185 and fills the backside cavity of the first PFET source/drain 140A. The protrusion portion of the backside contact 195P having a total depth/dimension/height D3 as illustrated in FIG. 9. FIG. 10 illustrates that the protrusion portion of the backside contact 195P includes the depth/dimension D6 of the first backside interlayer dielectric layer 185 and the range of depths D4 in which the protrusion portion of the backside contact 195P extends/gouges into the first PFET source/drain 140A. As described in greater detail at FIG. 6, the depth/dimension D6 of the first backside interlayer dielectric layer 185 is equal/substantially similar to the depth/dimension of the source/drains 140A/140B extending past the backside surface of the gate 130. Accordingly, the depth/dimension D6 of the protrusion portion of the backside contact 195P may vary according to the depth/dimension of the source/drains 140A/140B extending past the backside surface of the gate 130. The depth/dimension D4 of the protrusion portion of the backside contact 195P additionally depends on the gouging process described in detail at FIG. 9. The depth/dimension D4 may range from the backside surface of the first channel layer 125 (i.e., the channel closest to the backside region) to any range of depths/dimensions within the first PFET source/drain 140A depending on the gouging process described in detail at FIG. 9.

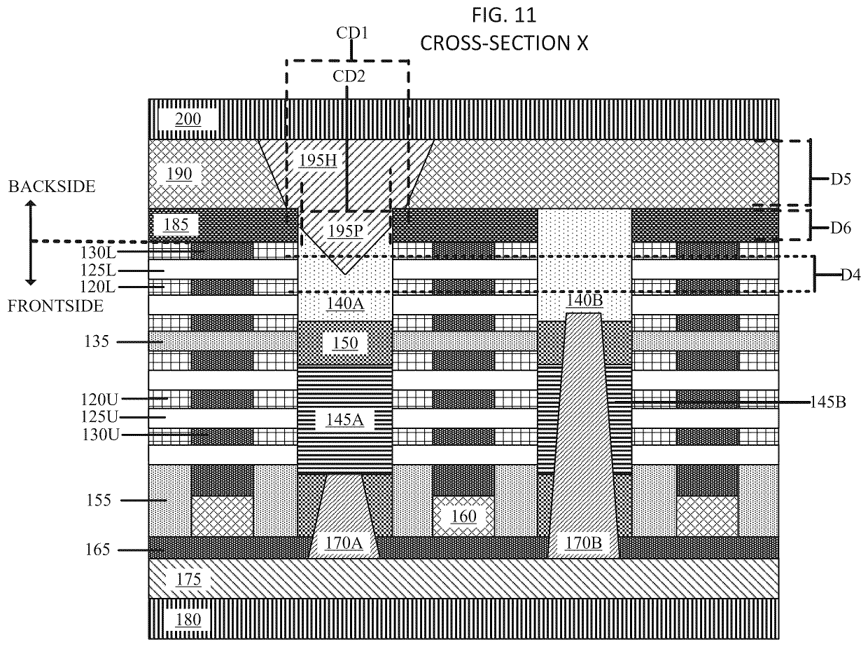

Additionally, the protrusion portion of the backside contact 195 in FIG. 10 illustrates a triangular shape, this is not meant to be seen as limiting to the present invention, the shape of the protrusion portion of the backside contact 195P can also be a concave shape, trapezoidal shape, some other shape and/or combination of shapes. Furthermore, the protrusion portion of the backside contact 195P traverses the width of the first PFET source/drain 140A. As will be described in further detail at FIG. 11 the head portion of the backside contact 195H may have a critical dimension/width greater than the critical dimension/width of the protrusion portion of the backside contact 195P.

FIG. 11 illustrates the processing stage after the formation of the backside interconnect 200. The stacked FET will now be referred to as a lower FET and an upper FET, where the lower FET is located closer to the backside region. The inner spacers 120 will now be referred to as lower inner spacers 120L and upper inner spacers 120U. The channel layers 125 will now be referred to as lower channel layers 125L and upper channel 125U for clarity reasons. The gates 130 will now be referred to as lower gates 130L and upper gates 130U for clarity reasons. The backside interconnect 200 is formed on the backside surface of the second backside interlayer dielectric layer 190 and the backside surface of the backside contact 195. The backside interconnect 200 can be comprised of one or more layers/levels, one or more via(s), and one or more metal lines. The backside interconnect 200 is illustrated as one layer for simplicity reasons only.

The head portion of the backside contact 195H being within/horizontally adjacent to the second backside interlayer dielectric layer 190. The head portion of the backside contact 195H having a depth/dimension D5 equivalent/substantially similar to the depth/dimension of the second backside interlayer dielectric layer 190.

The protrusion portion of the backside contact 195P being within/horizontally adjacent to the first backside interlayer dielectric layer 185 and filling the backside cavity of the first PFET source/drain 140A. The protrusion portion of the backside contact 195P having depth equal to the combined depth/dimension of D6 and the depth/dimension D4 of the extension beyond the backside surface of the lower gate 130L and lower inner spacers 120L into the first PFET source/drain 140A which may range from the backside surface of the first channel layer 125L (i.e., the channel closest to the backside region) to any range of depths/dimensions within the first PFET source/drain 140A as illustrated by the ranges of depths/dimensions D4. The ranges of depths/dimension D4 is not meant to be limiting, the depths/dimension of the protrusion portion of the backside contact may be shallower or deeper than the ranges of depths/dimensions D4 illustrated.

FIG. 11 further illustrates the critical dimension/width of the head portion of the backside contact 195H and critical dimension/width of the of the protrusion portion of the backside contact 195P. The critical dimension/width of the head portion of the backside contact 195H is emphasized using dashed bracket CD1 and the critical dimension/width of the protrusion portion of the backside contact 195P is emphasized using dashed bracket CD2, this is not meant to be seen as limiting to the present invention. As described in detail at FIG. 8 the alignment, size, shape, and location of the head portion of the backside contact trench 191 may depend on variations in the fabrication process, which may correspond with variations in the critical dimension width of the head portion of the backside contact 195H. In FIG. 11, the CD1 depicts the narrowest portion of the critical dimension/width for the head portion of the backside contact 195H while CD2 depicts the widest portion of the critical dimension/width of the protrusion portion of the backside contact 195P. FIG. 11 illustrates the critical dimension/width of the head portion CD1 as being greater than the critical dimension width of the protrusion portion CD2 of the backside contact 195. In other embodiments, the critical dimension widths of both the head portion and the protrusion portion may vary, however, the critical dimension/width of the protrusion portion consistently traverses the width of the first PFET source/drain 140A which increases the overlap of the backside contact 195 with the PFET source/drain 140A cavity which is critical for aspects of the FET performance, including reducing contact resistance.

The protrusion portion of the backside contact 195P traversing the width of the first PFET source/drain 140A deceases the total depth of the first PFET source/drain 140A as compared to the second PFET source/drain 140B. The total depth of the second PFET source/drain 140B still includes depth/height/dimension D2 illustrated by FIG. 6. The total depth of the first PFET source/drain 140A no longer includes the full depth/height/dimension D2 following the gauging process described at FIG. 9. As illustrated by FIG. 11, PFET source/drain 140B extends past the backside surface of the lower gate 130L into the backside region of the stacked FET at a depth/dimension/height D6. In contrast, PFET source/drain 140A extends past the backside surface of the lower gate 130L into the backside region of the stacked FET at only a portion of the depth/dimension/height D6. Accordingly, the depth/dimension/height of the second PFET source/drain 140B is greater than the depth/dimension/height of the first PFET source/drain 140A. Furthermore, the first backside interlayer dielectric layer 185 is in contact with a first portion of the sidewall of the first PFET source/drain 140A and a second portion of the sidewall of the second PFET source/drain 140B. The second portion of the sidewall contact being greater than the first portion of the sidewall contact due to the gouging process of the first PFET source/drain 140A.

A microelectronic structure that includes a stacked FET that includes an upper FET and a lower FET, wherein the upper FET includes a NFET source/drain 145A and the lower FET includes a PFET source/drain 140A, the PFET source/drain 140A extending past a backside surface of a lower gate 130L of the lower FET into a backside region of the stacked FET. A first backside interlayer dielectric layer 185 located adjacent to a sidewall of the PFET source/drain 140A that extends into the backside region. A second backside interlayer dielectric layer 190 located on a backside surface of the first backside interlayer dielectric layer 185. A backside contact 195 located on a backside surface of the PFET source/drain 140A. The backside contact 195 including a head portion 195H and a protrusion portion 195P. The protrusion portion 195P of the backside contact 195 being horizontally adjacent to the first backside interlayer dielectric layer 185 and extending into the PFET source/drain 140A.

The first backside interlayer dielectric layer 185 being comprised of a first material. The second backside interlayer dielectric layer 190 being comprised of a second material. The first and second materials being different materials such that they are selectively etchable.

The protrusion portion of the backside contact 195P extending a depth/dimension into the PFET source/drain 140A. The depth/dimension D4 ranging between backside surface and a frontside surface of a channel layer 125L, wherein the channel layer is the closest channel layer 125L to the backside region.

The protrusion portion of the backside contact 195P extending into a frontside region to be on a same level as the lower gate 130L. The protrusion portion of the backside contact 195P having a triangular shape.

The head portion of the backside contact 195H being horizontally adjacent to the second backside interlayer dielectric layer 190. The depth/dimension D5 of the head portion of the backside contact 195H being equal to a depth/dimension D5 of the second backside interlayer dielectric layer 190.

The head portion of the backside contact 195H having a first dimension CD1 (e.g., first critical dimension/width CD1). The protrusion portion of the backside contact 195P having a second dimension CD2 (e.g., second critical dimension/width CD2). The first dimension CD1 (e.g., first critical dimension/width CD1) being greater than/larger than the second dimension CD2 (e.g., second critical dimension/width CD2).

A microelectronic structure that includes a first stacked FET. The first stacked FET includes a first upper FET and a first lower FET, wherein the first lower FET includes a includes a first PFET source/drain 140A. The first PFET source/drain 140A extending past a backside surface of a lower gate 130L into a backside region of the first stacked FET to a first depth. A second stacked FET. The second stacked FET includes a second upper FET and a second lower FET, the second lower FET including a second PFET source/drain 140B. The second PFET source/drain 140B extending past the backside surface of the lower gate 130L into a backside region of the second stacked FET to a second depth. The first depth and the second depth being different. A first backside interlayer dielectric layer 185 located adjacent to a sidewall of the first PFET source/drain 140A and adjacent to a sidewall of the second PFET source/drain 140B. The first backside interlayer dielectric layer 185 extending into the backside region of the first stacked FET and the backside region of the second stacked FET. A second backside interlayer dielectric layer 190 located on a backside surface of the first backside interlayer dielectric layer 185 and a backside surface of the second PFET source/drain 140B.

The first backside interlayer dielectric layer 185 being in contact with a first portion of the sidewall of the first PFET source/drain 140A and a second portion of the sidewall of the second PFET source/drain 140B. The contact surface of the second portion being greater than the contact surface of the first portion.

The second depth of the second PFET source/drain 140B being greater than the first depth of the first PFET source/drain 140A.

The microelectronic structure further includes a backside contact 195. The backside contact 195 includes a head portion 195H and a protrusion portion 195P. The protrusion portion 195P of the backside contact 195 is horizontally adjacent to the first backside interlayer dielectric layer 185 and gauges into the first PFET source/drain 140A.

The depth of the protrusion portion of the backside contact 195P is equal to a combined depth D3 of the first backside interlayer dielectric layer 185/D6 and the gauge into the first PFET source/drain 140A. The depth of the gauge into the first PFET source/drain 140A may be any number of depths within a depth/dimension/height range D4.

The protrusion portion of the backside contact 195P having a triangular shape and traversing a width of the first PFET source/drain 140A.

A method comprising forming a stacked FET that includes an upper FET and a lower FET. The upper FET includes a NFET source/drain 145A, and the lower FET includes a PFET source/drain 140A. The PFET source/drain 140A extending past a backside surface of a lower gate 130L of the lower FET into a backside region of the stacked FET. Forming a first backside interlayer dielectric layer 185 located adjacent to a sidewall of the PFET source/drain 140A that extends into the backside region. Forming a second backside interlayer dielectric layer 190 located on a backside surface of the first backside interlayer dielectric layer 185. Forming a backside contact 195 located on a backside surface of the PFET source/drain 140A. The backside contact 195 including a head portion 195H and a protrusion portion 195P. The protrusion portion 195P of the backside contact 195 is horizontally adjacent to the first backside interlayer dielectric layer 185. The protrusion portion 195P of the backside contact 195 extends into the PFET source/drain 140A.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a stacked FET that includes an upper FET and a lower FET, wherein the upper FET includes a NFET source/drain and the lower FET includes a PFET source/drain, wherein the PFET source/drain extends past a backside surface of a lower gate of the lower FET into a backside region of the stacked FET;
a first backside interlayer dielectric layer located adjacent to a sidewall of the PFET source/drain that extends into the backside region;
a second backside interlayer dielectric layer located on a backside surface of the first backside interlayer dielectric layer; and
a backside contact located on a backside surface of the PFET source/drain, wherein the backside contact includes a head portion and a protrusion portion, wherein the protrusion portion of the backside contact is horizontally adjacent to the first backside interlayer dielectric layer, and wherein the protrusion portion of the backside contact extends into the PFET source/drain.

2. The microelectronic structure of claim 1, wherein the first backside interlayer dielectric layer is comprised of a first material, and wherein the second backside interlayer dielectric layer is comprised of a second material.

3. The microelectronic structure of claim 2, wherein the first material and the second material are different materials.

4. The microelectronic structure of claim 1, wherein the protrusion portion of the backside contact extends a depth into the PFET source/drain.

5. The microelectronic structure of claim 4, wherein the depth is in a range between backside surface and a frontside surface of a channel layer, wherein the channel layer is the closest channel layer to the backside region.

6. The microelectronic structure of claim 1, wherein the protrusion portion extends into a frontside region to be on a same level as the lower gate.

7. The microelectronic structure of claim 1, wherein the protrusion portion of the backside contact has a triangular shape.

8. The microelectronic structure of claim 1, wherein the head portion of the backside contact is horizontally adjacent to the second backside interlayer dielectric layer.

9. The microelectronic structure of claim 8, wherein a depth of the head portion of the backside contact is equal to a depth of the second backside interlayer dielectric layer.

10. The microelectronic structure of claim 1, wherein the head portion of the backside contact has a first dimension, and wherein the protrusion portion of the backside contact has a second dimension.

11. The microelectronic structure of claim 10, wherein first dimension is larger than the second dimension.

12. A microelectronic structure comprising:
a first stacked FET, wherein the first stacked FET includes a first upper FET and a first lower FET, wherein the first lower FET includes a includes a first PFET source/drain, wherein the first PFET source/drain extends past a backside surface of a lower gate into a backside region of the first stacked FET to a first depth;
a second stacked FET, wherein the second stacked FET includes a second upper FET and a second lower FET, wherein the second lower FET includes a second PFET source/drain, wherein the second PFET source/drain extends past the backside surface of the lower gate into a backside region of the second stacked FET to a second depth, wherein the first depth and the second depth are different;
a first backside interlayer dielectric layer located adjacent to a sidewall of the first PFET source/drain and a sidewall of the second PFET source/drain, wherein the first backside interlayer dielectric layer extends into the backside region of the first stacked FET and the backside region of the second stacked FET; and
a second backside interlayer dielectric layer located on a backside surface of the first backside interlayer dielectric layer and a backside surface of the second PFET source/drain.

13. The microelectronic structure of claim 12, wherein the first backside interlayer dielectric layer is in contact with a first portion of the sidewall of the first PFET source/drain and a second portion of the sidewall of the second PFET source/drain.

14. The microelectronic structure of claim 13, wherein the second portion is greater than the first portion.

15. The microelectronic structure of claim 12, wherein the second depth is greater than the first depth.

16. The microelectronic structure of claim 12, further comprising:
a backside contact, wherein the backside contact includes a head portion and a protrusion portion, wherein the protrusion portion of the backside contact is horizontally adjacent to the first backside interlayer dielectric layer and gauges into the first PFET source/drain.

17. The microelectronic structure of claim 16, wherein a depth of the protrusion portion of the backside contact is equal to a combined depth of the first backside interlayer dielectric layer and the gauge into the first PFET source/drain.

18. The microelectronic structure of claim 16, wherein the protrusion portion of the backside contact has a triangular shape.

19. The microelectronic structure of claim 16, wherein the protrusion portion of the backside contact traverses a width of the first PFET source/drain.

20. A method comprising:
forming a stacked FET that includes an upper FET and a lower FET, wherein the upper FET includes a NFET source/drain and the lower FET includes a PFET source/drain, wherein the PFET source/drain extends past a backside surface of a lower gate of the lower FET into a backside region of the stacked FET;
forming a first backside interlayer dielectric layer located adjacent to a sidewall of the PFET source/drain that extends into the backside region;
forming a second backside interlayer dielectric layer located on a backside surface of the first backside interlayer dielectric layer; and
forming a backside contact located on a backside surface of the PFET source/drain, wherein the backside contact includes a head portion and a protrusion portion, wherein the protrusion portion of the backside contact is horizontally adjacent to the first backside interlayer dielectric layer, and wherein the protrusion portion of the backside contact extends into the PFET source/drain.
